(19) United States
(12) Patent Application Publication
(10) Pub. No.: US 2009/0194829 A1
(43) Pub. Date: Aug. 6, 2009

(54) MEMS Packaging Including Integrated Circuit Dies

(76) Inventors: Shine Chung, Taipei (TW); Fu-Lung Hsueh, Cranberry, NJ (US)

Correspondence Address: SLATER & MATSIL, L.L.P., 17950 PRESTON ROAD, SUITE 1000, DALLAS, TX, 75252, US

(21) Appl. No.: 12/269,298

(22) Filed: Nov. 12, 2008

Related U.S. Application Data
(60) Provisional application No. 61/025,174, filed on Jan. 31, 2008.

(51) Int. Cl. H01L 29/84; H01L 23/04

(52) U.S. Cl. 257/415; 257/704; 257/E29.324; 257/E23.181

(57) ABSTRACT

MEMS packaging schemes having a system-on-package (SOP) configuration and a system-on-board (SOB) configuration are provided. The MEMS package comprises one or more MEMS dies, a cap section having one or more integrated circuit (IC) dies, and a packaging substrate or a printed circuit board (PCB) arranged in a stacking manner. Vertical connectors, such as through-silicon-vias (TSVs), are formed to provide short electrical connections between the various components. The MEMS packaging schemes enable higher integration density, reduced MEMS package footprints, reduced RC delays and power consumption.

This application claims the benefit of U.S. Provisional Application No. 61/025,174 filed on Jan. 31, 2008, entitled “Apparatus and Method for RF Integration,” which application is hereby incorporated herein by reference.

### TECHNICAL FIELD

The present invention relates in general to micro-electromechanical system (MEMS) and more particularly to integrated MEMS devices with multiple integrated circuit dies in a system-on-package (SOP) or system-on-board (SOB) configuration.

### BACKGROUND

A MEMS device is the integration of miniature mechanical elements, sensors, actuators, and electronics on a common silicon substrate through micro-fabrication technology. A sensor on a MEMS device typically includes a miniature moveable structure, such as a bridge, cantilevered beam, suspended mass, membrane or capacitive element device. A sensor may gather information from the environment through measuring mechanical, thermal, biological, chemical, optical, and/or magnetic phenomena. The electronics then process the information derived from the sensors and through some decision making capability direct the actuators to respond by moving, positioning, regulating, pumping, and/or filtering, thereby controlling the environment for some desired outcome or purpose. MEMS devices have found applications in various commercial products.

The functionality, the sophistication and the application scope of MEMS devices can be brought to an unprecedented level and revolutionize nearly every product category by bringing together the powerful signal processing capability of an advanced integrated circuit (IC) with the sensing and responding capability of a MEMS device, making possible the realization of a true system-in-a-package (SIP). The ICs can be thought of as the “brains” of the system, while the MEMS devices can act as the “eyes” and “arms” to allow the micro-system to sense and control the environment.

As an example, a SIP may be developed, bringing together a 3-axis MEMS acceleration sensor with signal processing ICs to form a motion-based controller of a video game. This controller enables a truly interactive, lifelike gaming experience for players of all ages by abandoning the traditional controller held with two hands. The game controller may allow players to run, jump, spin, slide, steer, accelerate, bank, dive, kick, throw and score in a way never experienced in the history of gaming.

As another example, a MEMS RF switch module may be combined with signal processing ICs to form a SIP in a wireless device, such as a cell phone, a wireless computer network, a communication system, or a radar system. A MEMS RF switch module can be used as an antenna switch, a mode switch, or a transmit/receive switch in a wireless device and provides significant technical benefits because of its low power characteristics and ability to operate in radio frequency ranges.

In an existing packaging approach of integrating a MEMS device with other signal processing ICs in an electronics system, electrical connectivity made to and from the MEMS device are typically made through electrical feed-throughs that emerge horizontally from the edges of the MEMS device. These horizontal feed-throughs increase the footprint size of the SIP. Among other drawbacks of an existing packaging approach, horizontal feed-throughs create crossing signal lines that may affect circuit performance, lengthy horizontal signal line routings may increase signal latency, and long metal traces may lead to undesirable inductance.

### SUMMARY OF THE INVENTION

These and other problems are generally solved or circumvented, and technical advantages are generally achieved, by preferred embodiments of the present invention which provide MEMS packaging schemes that provide a system-on-package (SOP) configuration and a system-on-board (SOB) configuration. The MEMS package comprises one or more MEMS dies, a cap section having one or more integrated circuit (IC) dies, and a packaging substrate or a printed circuit board (PCB) arranged in a stacking manner. Vertical connectors, such as through-silicon-vias, are formed to provide short electrical connections between the various components. The MEMS packaging schemes enable higher integration density, reduced MEMS package footprint, reduced RC delays and power consumption.

In one preferred embodiment, a micro-electromechanical system (MEMS) comprises a MEMS device having a first plurality of terminals, a cap section including at least one pass-through via and at least one microelectronic device, and a second plurality of terminals, wherein the MEMS device and the cap section are electrically coupled through the first plurality and the second plurality of terminals.

In another preferred embodiment, an apparatus comprises a micro-electromechanical system (MEMS) device that comprises at least one electronic circuit, the at least one electronic circuit being electrically coupled to at least one terminal on a first surface of the MEMS device. The apparatus also comprises a cap section underlying the MEMS device; the cap section comprises at least one semiconductor device, wherein the at least one semiconductor device is electrically coupled to the at least one electronic circuit in the MEMS device through a plurality of terminals on the MEMS device, and wherein the at least one semiconductor device is also electrically coupled to at least one contact on a first connecting surface of the cap section through internal metal interconnections and at least one pass-through via in the cap section. The apparatus further comprises a substrate underlying the cap section comprising at least one contact on a supporting surface.

### BRIEF DESCRIPTION OF THE DRAWINGS

For a more complete understanding of the present invention, and the advantages thereof, reference is now made to the following descriptions taken in conjunction with the accompanying drawing, in which:

FIG. 1 is an expanded view illustrating the electronic components included in an embodied MEMS package;

FIG. 2A is a cross sectional view of a MEMS package in an illustrated embodiment;

FIG. 2B is a top view of the MEMS package in accordance with FIG. 2A;

FIG. 3 is a top view of a MEMS package in an illustrated embodiment; and

FIGS. 4-9 are cross-sectional views of illustrative embodiments of MEMS package.

### DETAILED DESCRIPTION OF ILLUSTRATIVE EMBODIMENTS

The making and using of the presently preferred embodiments are discussed in detail below. It should be appreciated, however, that the present invention provides many applicable inventive concepts that can be embodied in a wide variety of specific contexts. The specific embodiments discussed are merely illustrative of specific ways to make and use the invention, and do not limit the scope of the invention.

The present invention will be described with respect to preferred embodiments in a specific context, namely apparatus and method of integrating MEMS devices with multiple integrated circuit dies and/or other electronic components in a system-on-package (SOP) or system-on-board (SOB) configuration. However, features, structures or characteristics described according to the preferred embodiments may also be combined in suitable manners to form one or more other embodiments. Also, for clarification, the figures are drawn only to illustrate the relevant aspects of the inventive features or characteristics, and are not drawn to scale.

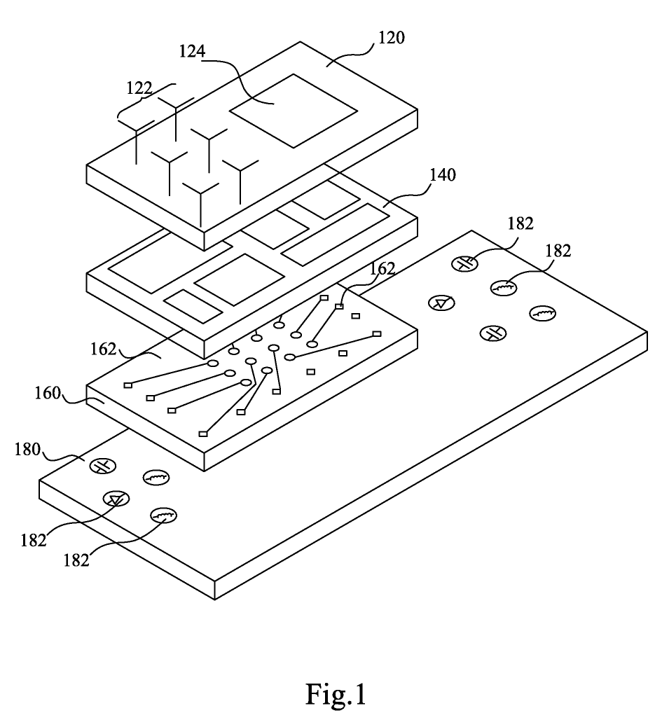

FIG. 1 shows an expanded top view, illustrating some of the major components involved in the various MEMS packaging configurations in preferred embodiments. Among the components are MEMS device 120, cap section 140, interposer 160, and package substrate or printed circuit board (PCB) 180. MEMS device 120 comprises sensor structure portion 122 and electronic circuit 124; cap section 140 includes one or more semiconductor integrated circuits, microwave micro-strip circuits, or other like miniaturized electronic circuits; interposer 160 comprises passing-through structures 162 to provide electrical adaptation between contacts with small pitch on cap section 140 and contacts with large pitch on a connecting surface of packaging substrate or PCB 180. Interposer 160 may be made of various suitable materials and have different configurations depending on application. While PCB 180 is preferably a printed circuit board, it may comprise one or more circuit elements 182 formed from thereon. Circuit elements 182 may comprise active, passive, or a combination of active and passive elements, such as transistors, diodes, resistors, capacitors, and inductors. The arrangement of the various components in FIG. 1 serves to illustrate an inventive feature that one or more MEMS dies may be integrated with other electronic components to form a MEMS package in preferred embodiments. As will be described in detail later, these components may be combined, rearranged, and electrically connected through various techniques to form the various MEMS package configurations in the various embodiments of the present invention.

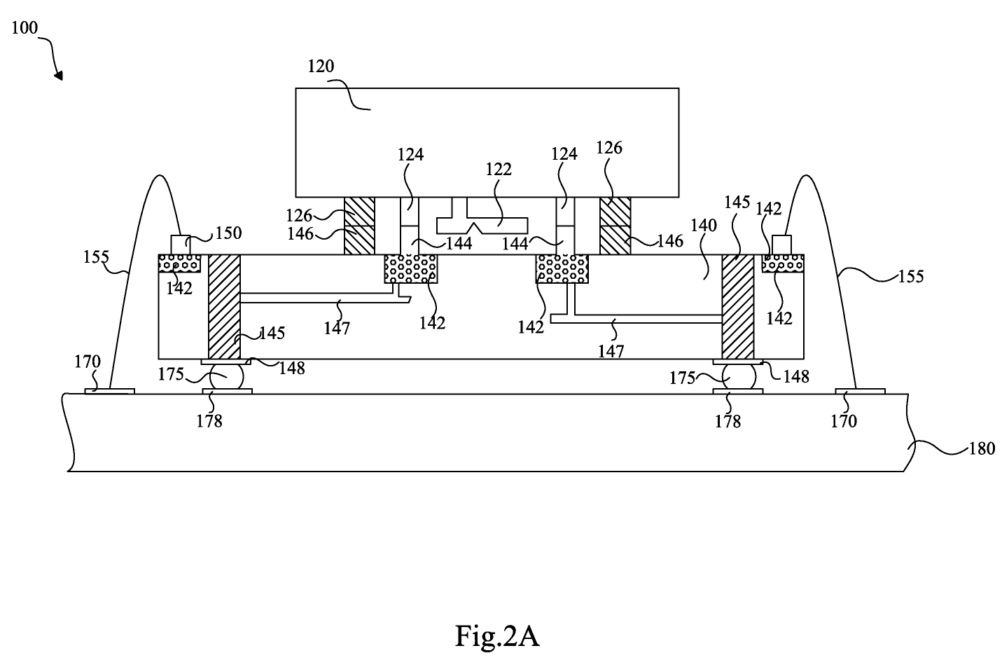

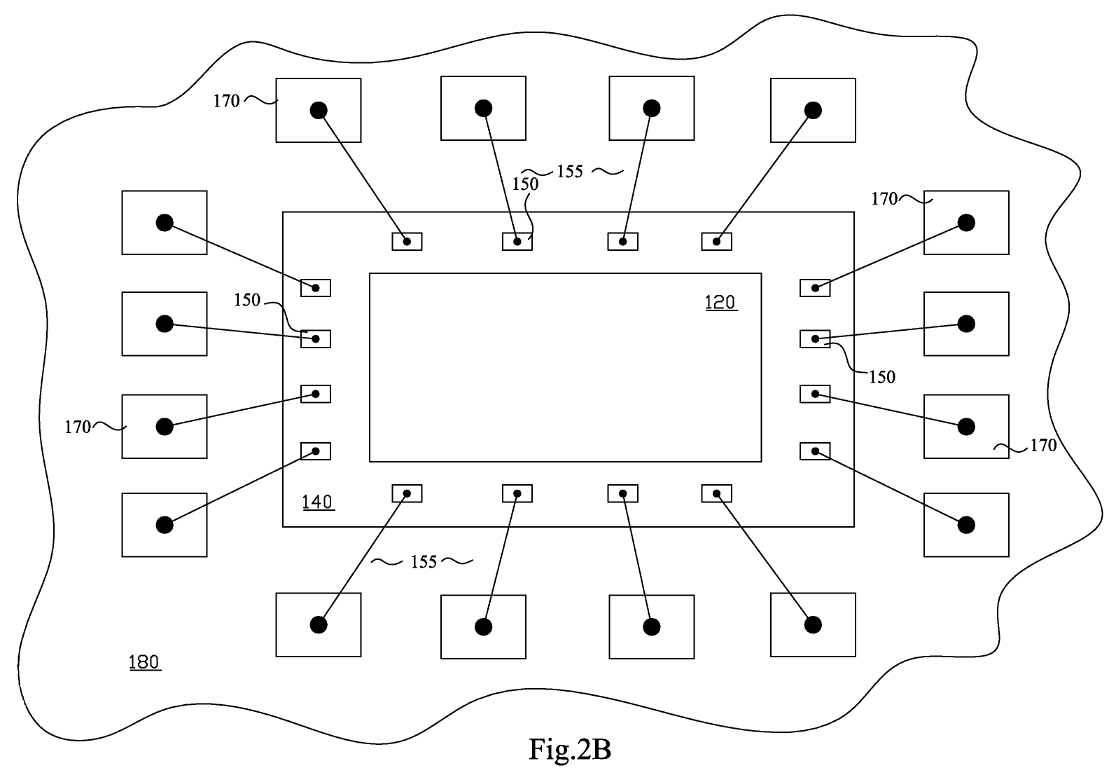

Referring now to FIG. 2A, a cross sectional view of MEMS package 100 in one preferred embodiment is illustrated. MEMS package 100 includes MEMS device 120, cap section 140, and packaging substrate 180, one stacking atop the other. In the current preferred embodiment, the sensor portion of MEMS device 120 includes an RF switch module 122 with miniature movable components projecting over a connecting surface. RF switch module 122 may be used in a wireless communication terminal, and can switch from one RF band to another RF band to transmit an RF signal. While only one RF switch is shown for clarity, there may be many RF switches formed in switch module 122. MEMS device 120 also typically comprises electronic circuits, such as MEMS control circuits, that process the signals derived from RF switch module 122 and direct the processed signals to the other components of MEMS package 100 through conductive terminals 124. In other preferred embodiments, MEMS device 120 includes one or more of a microphone, a speaker, an inertial sensor, a pressure sensor, an RF tunable device, a relay, or the like.

Cap section 140 includes one or more semiconductor devices or integrated circuits 142, such as a digital IC, an analog IC, a MEMS control IC, a mixed-signal IC, a microprocessor, a memory IC, or an IC in a system-on-a-chip (SOC) configuration, and/or one or more micro-strip circuits, such as micro-strip filter, micro-strip resonator, or the like, and various combinations of the foregoing. These circuits are typically formed on materials, such as semiconductor material, ceramic, glass, and plastic, through microelectronic processing techniques, such as film deposition, photolithography, wet and dry etching, and electroplating. These microelectronic circuits in cap section 140 are indicated as 142 in FIG. 2A for clarification. Also, a plurality of conductive terminals 144 is disposed on the top surface of cap section 140. Also, conductive contacts 148 are mounted to the bottom of the cap section 140. Terminals 144 are coupled to terminals 124 on MEMS device 120, enabling electrical connections between the electronic circuits in MEMS device 120 and microelectronic circuits 142 in cap section 140. Although terminals 124 and 144 are shown as generally straight leads in FIG. 2A, they are not limited to this configuration. Other suitable low-resistance connectors, such as contacts, balls, and pads may also be used to make electrical connections between the electronic circuits in MEMS device 120 and microelectronic circuits 142 in cap section 140.

In one preferred embodiment, MEMS package 100 includes seal ring 126 attached to a surface of MEMS device 120, and seal ring 146 attached to a surface of cap section 140. When MEMS device 120 and cap section 140 are coupled together, seal rings 126 and 146 are pressed together to form a sealed enclosure. The enclosure thus formed is preferably used to house a sensor portion, such as switch module 122 of MEMS device 120 and protect the movable components of switch module 122 from detrimental effects, such as mechanical touching, electrical interference, and chemical contamination. The enclosure or a portion of the enclosure may be pre-formed attaching to MEMS device 120, or attaching to cap section 140, or to both. In the current embodiment, seal rings 126 and 146 are metal. Seal rings 126 and 146 may be sealed using solder, gold thermocompression (TCB), gold thermosonic bonding (TSB), or the like. Alternatively, one or both of the seal rings 126 and 146 could be formed of other suitable materials, including pliable materials such as plastics, polymers, epoxies, and the like.

MEMS package 100 also includes vias 145 that pass through cap section 140 to electronically couple cap section 140 to underlying package substrate or printed circuit board 180 through contacts 148. In one preferred embodiment, cap section 140 comprises a silicon-based semiconductor IC, and vias 145 are electroplated or otherwise filled with a metal conductor, such as aluminum, copper, tungsten, and the like. In another preferred embodiment, cap section 140 is a micro-strip circuit formed on a ceramic substrate. Vias 145 are formed by punching holes in the ceramic according to a pre-defined pattern and filling the holes with metal materials. For description convenience, vias 145 are commonly referred to as through-silicon-vias (TSVs) in the following description, although cap section 140 should not be limited to silicon. TSVs 145 are electrically coupled to microelectronic circuits 142 through metal interconnections 147 that are formed in the various interconnect metal layers of cap section 140. Contacts 148 on cap section 140 and contacts 178 on packaging substrate 180 are electrically and physically coupled through solder balls 175, although other suitable low-resistance connectors may also be used. When structure 180 is a packaging substrate, contacts 178 may be, in turn, electrically coupled to package leads. When structure 180 is a PCB, contacts 178 may be, in turn, electrically coupled to one or more circuit elements (not shown) on PCB 180. Moreover, wire bond pads 150 and 170 may also be formed on the top surfaces of cap section 140 and packaging substrate 180, respectively. Wire bond pads 150 and 170 may be, in turn, coupled to microelectronic circuits 142 in cap section 140 and package leads or circuit elements on structure 180, respectively. Additional electrical connections between cap section 140 and packaging substrate or PCB 180 may be made through wire bond 155, which is bonded to wire bond pad 150 at one end and wire bond pad 170 at the other end.

In one preferred embodiment, electronic circuits in MEMS device 120 are first coupled to microelectronic circuits 142 in cap section 140 through conductive terminals 124 and 144. Signals processed from microelectronic circuits 142 are then directed to circuit elements on substrate 180 through TSVs 145 and/or wire bond 155, or both. There is preferably no direct electrical connection between electronic circuits in MEMS device 120 and package leads or circuit elements on substrate 180. As one advantage, electrical surges on substrate 180 may be isolated and will not affect the performance of MEMS device 120. Also, in the current preferred embodiment, MEMS device 120 is small and occupies a tiny portion of the surface area on cap section 140, and terminal 124 pitch on MEMS device 120 is significantly smaller than that of TSVs 145 in cap section 140. The current MEMS packaging configuration may facilitate integrating a small MEMS die having a small terminal pitch to a substrate that has a large solder ball contact or wire bond pad pitch, where cap section 140 also provides adaptation between the unmatched terminal pitch sizes on MEMS device 120 and on substrate 180, among other advantages.

In an additional and/or alternative preferred embodiment, MEMS device 120 is sandwiched between cap section 140 and substrate 180. MEMS RF module 122 is sealed in an enclosure between the bottom surface of cap section 140 and the top surface of substrate 180. MEMS terminals and seal rings used in the alternative embodiment are similar to terminals 124 and 144, and seal rings 126 and 146, described with respect to FIG. 2A. The alternative embodiment is preferably used where the size of MEMS device 120 is large and, if disposed over the top surface of cap section 140, may occupy a significant portion of the surface areas on cap section 140, which is typically undesirable.

The MEMS packaging configuration described above provides a number of benefits. On the one hand, coupling a MEMS device to one or more ICs with powerful signal processing capacity may significantly increase the functionality, the sophistication and the application scopes of the MEMS device. On the other hand, integrating a MEMS device into an electronic system having one or more ICs may enable the electronic system to hear, see, and feel its surroundings and, through some complex decision making capability, to direct actuators on a MEMS device to respond by moving, positioning, regulating, pumping, and/or filtering, thereby controlling the environment for some desired outcome or purpose. Also, this may significantly expand the functionality, the sophistication and the application scopes of an integrated electronic system. Other benefits include that the stacking MEMS packaging configuration shall provide higher circuit density when compared with conventional packaging schemes with horizontal feed-throughs. Also, terminals 124, 144, TSVs 145, and solder balls 175 provide vertical connections that are the shortest paths between the electronic circuits in MEMS device 120, cap section 140, and PCB 180, thus reducing the RC delays and power consumption by bringing microelectronic circuit modules much closer electrically. A top view of the current MEMS packaging configuration is shown in FIG. 2B.

There are very large numbers or varieties of alternative embodiments in packaging one or more MEMS devices with other electronic components. To clarify description and avoid repetition, like numerals and letters used to describe MEMS package 100 above are used for similar elements in the various alternative embodiments and the corresponding figures. Also, reference numerals described previously may not be described again in detail herein.

It is noted, for the purposes of clarifying description and avoiding repetition, substrate 180 in the alternative embodiments may be either referred to as a packaging substrate or a PCB. When substrate 180 is referred to as a packaging substrate, it typically comprises solder ball contacts and/or wire bonding pads electrically coupled to the packaging leads, which may be, in turn, connected to the outside world; while when substrate 180 is referred to as a PCB, it typically comprises solder ball contacts and/or wire bonding pads electrically coupled to the circuit elements on the same PCB board. Also, substrate 180 described in a certain preferred embodiment should not be limited to a specific configuration. For example, when it is referred to as a packaging substrate, it may also indicate a PCB and vice versa. When substrate 180 is a packaging substrate, the embodied MEMS package is commonly known to have a system-on-package configuration; when substrate 180 is a PCB having one or more circuit elements, the embodied MEMS package is commonly known to have a system-on-board configuration.

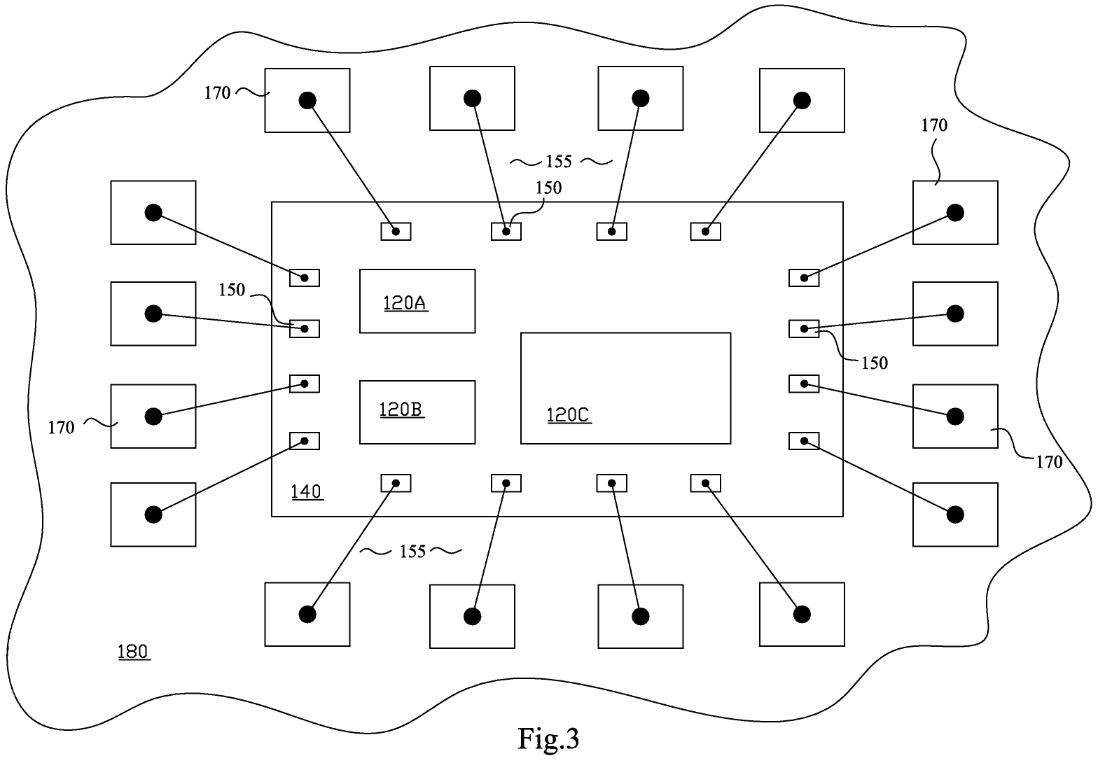

FIG. 3 is a top view illustrating another preferred embodiment of the present invention, where MEM dies 120A, 120B, and 120C are formed atop cap section 140 which preferably includes an IC in a SOC configuration. Cap section 140 is, in turn, stacked atop substrate 180. MEM dies 120A, 120B, and 120C may be electrically and physically coupled to the microelectronic circuits and circuit elements in cap section 140 and substrate 180 in a similar manner shown with respect to FIG. 2A. Wire bonds 155 may also be used to couple the microelectronic circuits in cap section 140 and circuit elements on substrate 180 through pads 150 and 170 on the top surfaces on cap section 140 and substrate 180, respectively.

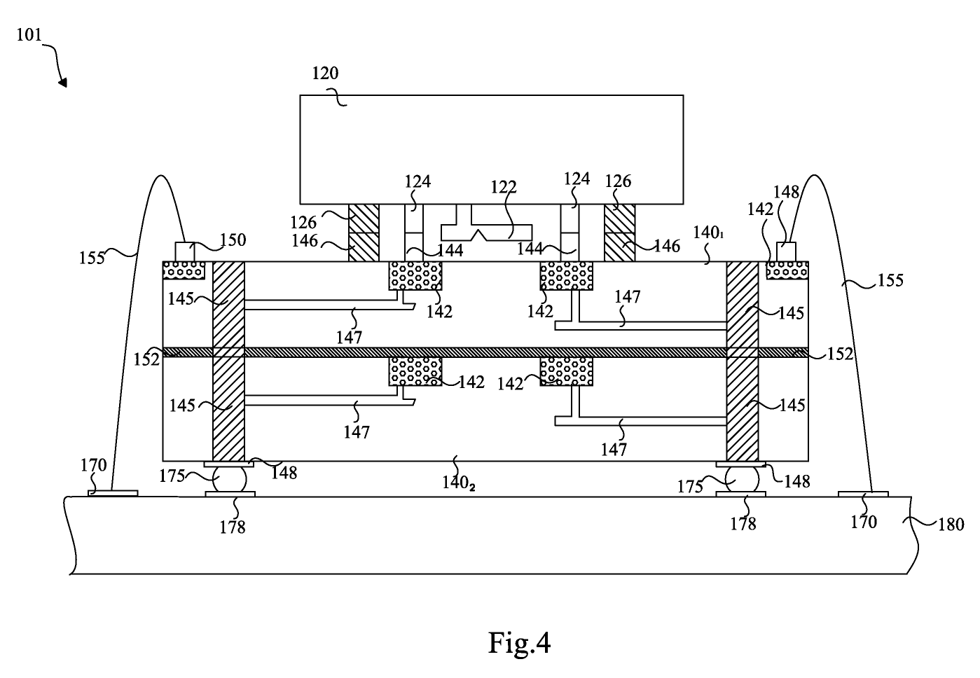

FIG. 4 illustrates a cross-sectional view of MEMS package 101 in one preferred embodiment of the present invention where cap section 140 has a multi-layer configuration, including top cap layer 140₁ and bottom cap layer 140₂. Cap layers 140₁ and 140₂ may be electrically isolated from each other through insulating layer 152. Each of cap layers 140₁ and 140₂ may comprise semiconductor material, ceramic material, glass, plastic, and the like. Also, microelectronic circuits and/or active or passive semiconductor devices may be formed in each of cap layers 140₁ and 140₂. In one preferred embodiment, at least one of cap layers 140₁ and 140₂ includes an IC having an SOC configuration. The microelectronic circuits 142 formed in the different cap layers may be electrically coupled together through TSVs 145 formed passing cap layer 140₁ and 140₂ and insulating layer 152. In one preferred embodiment, TSVs 145 in the different cap layers are aligned, as shown in FIG. 4, and have a TSV pitch significantly greater than the spacing between the MEMS die terminals 124. In another preferred embodiment, the TSV 145 pitches in the different cap layers increase from top cap layer 140₁ to an underling cap layer, such as bottom cap layer 140₂, so that the cap section can adapt a MEM die having a small terminal pitch to a substrate having a large solder ball contact pitch. Similarly, electrical connections between the microelectronic circuits 142 in the cap section and circuit elements on substrate 180 may be made through solder balls 175 or wire bonds 155 or both in a similar manner as those described with respect to FIG. 2A.

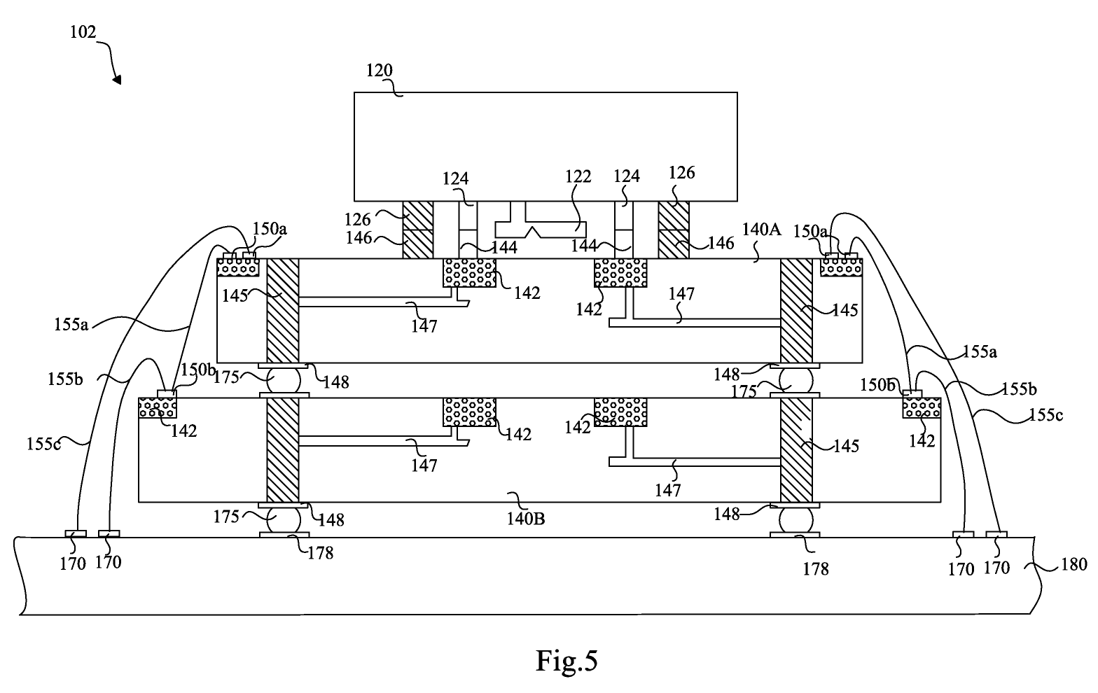

FIG. 5 shows a cross-sectional view of MEMS package 102 in another preferred embodiment where multiple cap sections, such as cap sections 140A and 140B, are stacked in the MEMS package. Each of the cap sections 140A and 140B may comprise silicon, ceramic material, glass, plastic, and the like. Also, microelectronic circuits and/or active or passive semiconductor devices may be formed in each of the cap sections. Unlike the cap section shown in FIG. 4, cap section 140A and 140B may be each pre-fabricated with passivated connecting surfaces, on which wire bonding pads 150a, 150b and/or solder ball contacts 148 are pre-formed. TSVs 145 are formed in each of cap sections 140A and 140B, coupling microelectronic circuits 142 to solder ball contacts 148. Solder balls 175 are, in turn, used to electrically couple cap section 140A to 140B, and 140B to PCB 180. Moreover, electrical connections between the microelectronic circuits 142 in cap section 140A and 140B may be also made through wire bond 155a, which couples wire bond pad 150a on the back side of cap section 140A and wire bond pad 150b on the back side of cap section 140B. Also as shown in FIG. 5, a wire bond pad 150b on the back side of cap section 140B may be connected to bond pad 170 on the top surfaces of PCB 180 through wire bond 155b, electrically coupling microelectronic circuits 142 in cap sections 140A and 140B to circuit elements in PCB 180. Additionally, wire bond 155c may be formed from wire bond pad 150a on the back side of cap section 140A to bond pad 170 on the top surfaces of PCB 180, making a direct coupling between microelectronic circuits 142 in cap section 140A to circuit elements on PCB 180. Thus, it is seen that the current embodiment provides great flexibility in making electrical connections between electronic circuits in the various components in the MEM package. The current embodiment is also conveniently referred to have a package-on-package configuration due to the stacked cap sections.

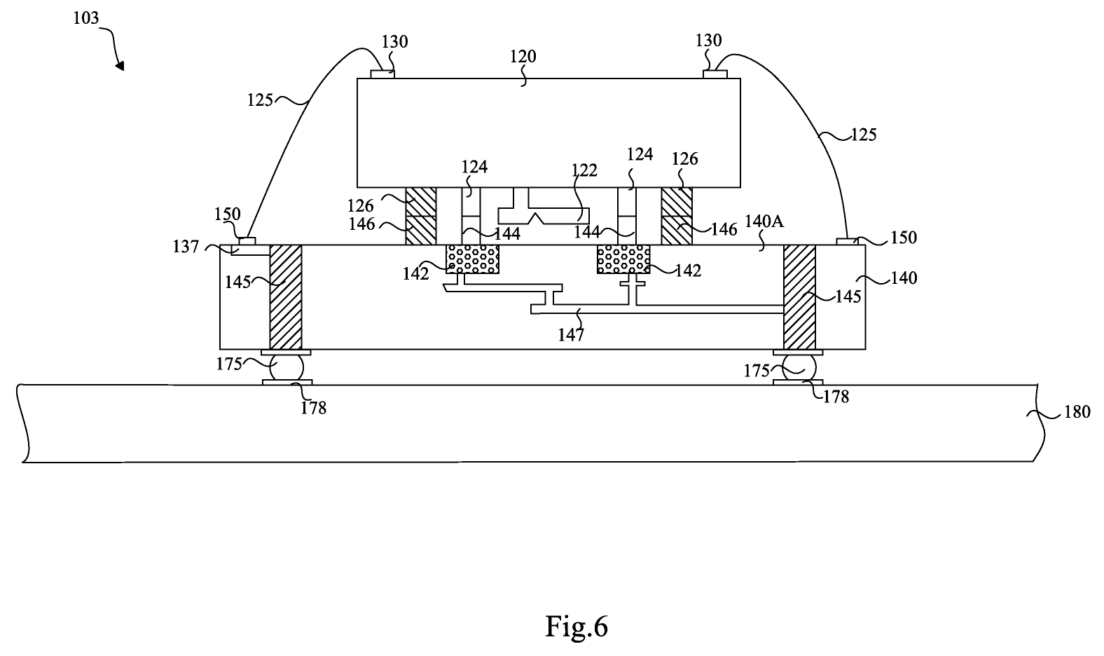

FIG. 6 illustrates a cross-sectional view of MEMS package 103 in a further preferred embodiment. MEMS package 103 may have a system-on-package configuration, where substrate 180 is a packaging substrate. MEMS package 103 may also have a system-on-board configuration, where substrate 180 is a PCB and comprises various circuit elements. The current embodiment differs from the preferred embodiments described previously in at least the following way. Wire bond pads 130 are formed on the back side of MEMS device 120, electrically coupled to the sensors and/or electronic circuits in MEMS device 120. Wire bonds 125 are formed between wire bond pads 130 on the back side of MEMS device 120 and wire bond pads 150 on the back side of cap section 140. Bond pads 150 may be, in turn, coupled to solder ball contacts 178 on packaging substrate 180 through metal traces 137, TSVs 145 in cap section 140, and solder balls 175. Similar to the embodiments described previously, electrical signals from MEMS device 120 are also coupled to the microelectronic circuits 142 in cap section 140 through terminals 124 and 144, processed and directed to packaging substrate 180 through metal interconnect 147, TSVs 145, and solder balls 175. The current embodiment provides a direct electrical path between MEMS device 120 and substrate 180, bypassing microelectronic circuits 142 in cap section 140. In a preferred embodiment, MEMS device 120's size is significantly smaller than the TSV 145 pitch in cap section 140. A MEMS oscillator is formed in the current MEMS packaging configuration, for example.

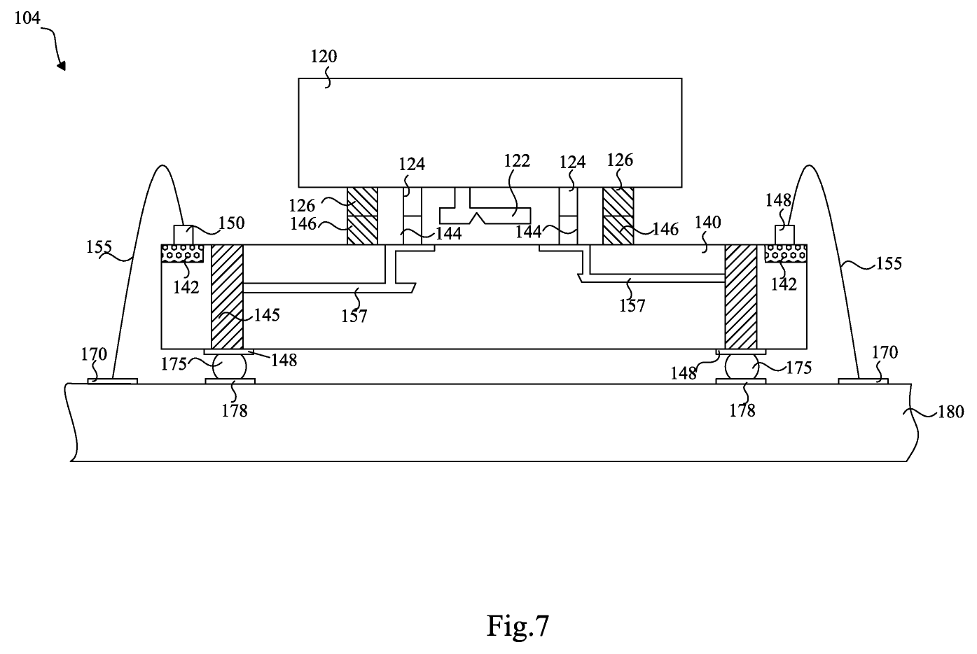

FIG. 7 is a cross sectional view illustrating MEMS package 104 in another preferred embodiment of the present invention. Unlike the preferred embodiments described previously, where signals from MEMS device 120 are coupled and processed in microelectronic circuits 142 in cap section 140, signals from MEMS device 120 are directed to substrate 180 through metal interconnects 157, TSVs 145, and solder balls 175, without being processed in cap section 140. In other words, electrical signals from MEMS device 120 are directly brought to the package leads or to the PCB board through TSVs 145. In the meantime, microelectronic circuits 142 in cap section 140 may be coupled to substrate 180 through wire bonds 155 and/or TSVs 145. In one preferred embodiment, cap section 140 includes TSVs that have much greater pitch than that of the terminals 124 on MEMS device 120. In another preferred embodiment, multi-level metal interconnects 157, as shown, are formed in cap section 140 to adapt MEMS die terminals 124 having small terminal pitch to TSVs 145 in cap section 140 and solder ball contacts 178 on substrate 180 having a much greater pitch. Also, cap section 140 may have a multi-layer configuration, and the TSV pitches in the cap layer stack may increase from a top cap layer to an underlying cap layer so that the cap section can electrically adapt a MEM die having small terminal pitch to a large substrate having a large solder ball pitch. In one preferred embodiment, MEMS die 104 includes RF switch modules that can be used as antenna switches, mode switches, and transmit/receive switches.

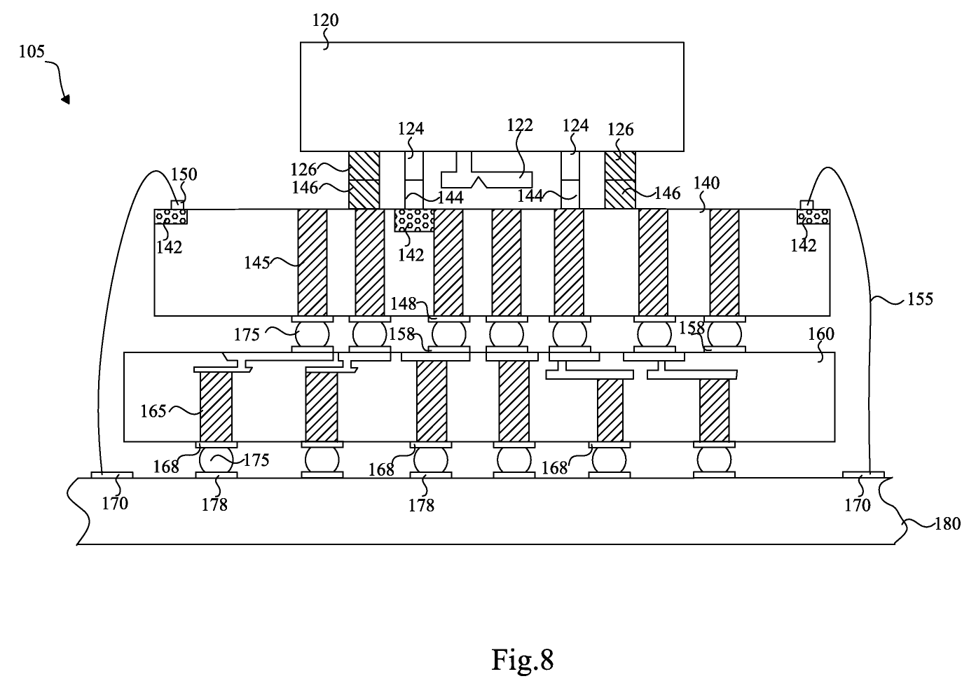

Referring to FIG. 8, a cross sectional view of MEMS package 105 according to another preferred embodiment is shown. Like the MEMS package described previously, MEMS package 105 comprises one or more MEMS device 120, one or more cap section 140, and packaging substrate or PCB 180. However, MEMS package 105 further includes silicon interposer 160 formed between cap section 140 and packaging 180. Silicon interposer 160 comprises conductive pads 158 on a top connecting surface having pad pitch matching to that of TSVs 145 in cap section 140. Silicon interposer 160 also comprises conductive pads 168 on a bottom connecting surface having pad pitch matching to that of solder ball pads 178 on substrate 180. Silicon interposer 160 further comprises TSVs 165 to provide direct conductive pathway between conductive pads 158 and 168. Solder balls 175 are formed between conductive pads 148 and 158 to provide electrical connections between cap section 140 and interposer 160. Solder balls 175 are also formed between conductive pads 168 and 178 to provide electrical connections between interposer 160 and substrate 180. As a result, electrical adaptation is made between the ICs in cap section 140 and substrate 180. In other preferred embodiments, interposer 160 may be also made of other suitable materials and have different configurations.

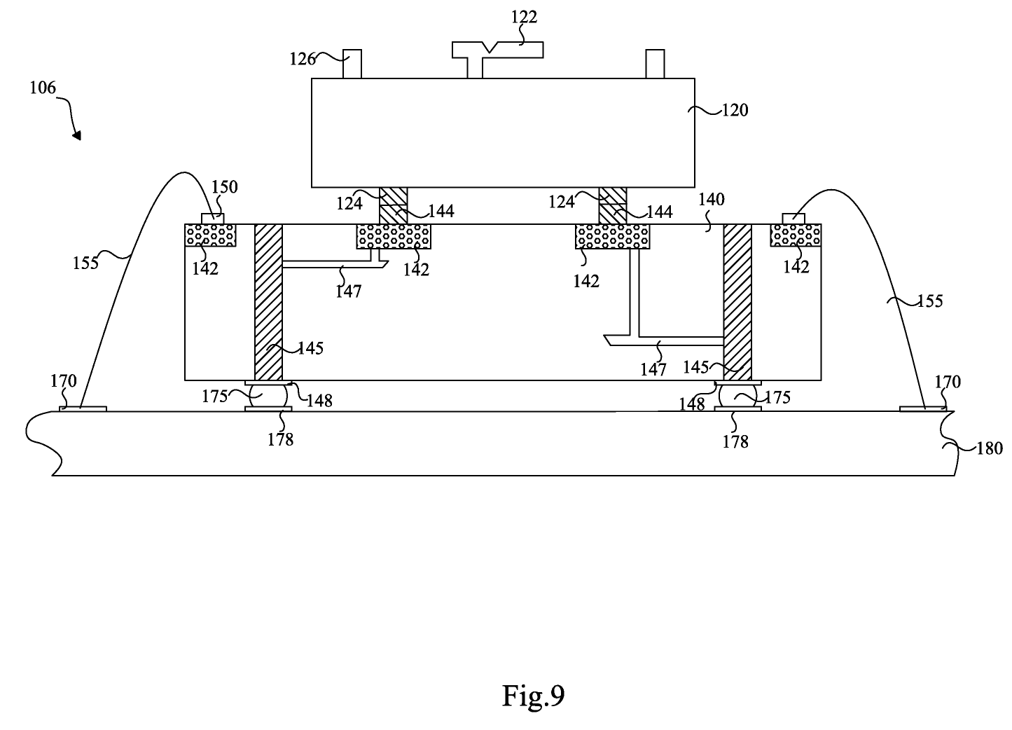

FIG. 9 illustrates MEMS package 106 in an additional preferred embodiment of the present invention. Compared with the embodied MEMS packages described above, sensor portion 122 of the current embodiment is not formed in the enclosure sealed between MEMS device 120 and cap section 140. Instead, MEMS die 120 is flipped so that the electrical coupling to cap section 140 is made on a connecting surface other than the surface where the sensor portion 122 is disposed. Electrical connections between the electronic circuits in MEMS device 120 and microelectronic circuits 142 in cap section 140 may be made through terminals 124 and 144, or other suitable low-resistance connectors, such as contacts, balls, and pads. Also, the aforementioned electrical connection may be made after MEMS device 120 and cap section 140 are each separately processed, and passivated. Similarly, TSVs 145 are formed in cap section 140 electrically coupling microelectronic circuits 142 to the circuit elements on PCB 180. The current embodiment is preferably used where the size of MEMS device 120 is large and occupies a significant portion of the surface areas on cap section 140. In an alternative preferred embodiment, a plurality of MEMS dies may be bonded on a cap section 140 using the methods described above.

Although the present invention and its advantages have been described in detail, it should be understood that various changes, substitutions and alterations can be made herein without departing from the spirit and scope of the invention as defined by the appended claims. As an example, it will be readily understood by those skilled in the art that components, materials, and configurations according to the preferred embodiments described above may be varied, substituted, combined to form even more MEMS packaging schemes, while remaining within the scope of the present invention.

Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

What is claimed is:

1. A micro-electromechanical system (MEMS), comprising:
a MEMS device having a first plurality of terminals; and
a cap section including at least one pass-through via and at least one microelectronic device, and a second plurality of terminals;
wherein the MEMS device and the cap section are electrically coupled through the first plurality and the second plurality of terminals.

2. The MEMS of claim 1, further including a seal ring formed in a space between the MEMS device and the cap section, the seal ring enclosing a projected sensor portion of the MEMS device.

3. The MEMS of claim 1, being selected from the group consisting of an RF switch, a microphone, a speaker, an inertial sensor, a pressure sensor, an RF tunable device, a relay, and any combinations thereof.

4. The MEMS of claim 1, wherein the cap section comprises at least one of a digital IC, an analog IC, a MEMS control IC, a mixed-signal IC, a microprocessor, a memory IC, an IC in a system-on-a-chip configuration, a micro-strip filter, a micro-strip resonator, and any combination thereof.

5. The MEMS of claim 1, wherein the cap section comprises a material selected from the group consisting essentially of: semiconductor material, ceramic, glass, plastic, and any combination thereof.

6. The MEMS of claim 1, wherein a pitch of the at least one pass-through via is significantly greater than that of the first plurality of terminals.

7. The MEMS of claim 1, further comprising a packaging substrate wherein the MEMS device, the cap section, and the packaging substrate are arranged in a stacking manner, forming a system-on-package (SOP) configuration.

8. The MEMS of claim 1, further comprising a printed circuit board (PCB) wherein the MEMS device, the cap section, and the PCB are arranged in a stacking manner, forming a system-on-board (SOB) configuration.

9. An apparatus, comprising:
a micro-electromechanical system (MEMS) device comprising at least one electronic circuit, the at least one electronic circuit being electrically coupled to at least one terminal on a first surface of the MEMS device;
a cap section underlying the MEMS device comprising at least one semiconductor device, wherein the at least one semiconductor device is electrically coupled to the at least one electronic circuit in the MEMS device through the at least one terminal on the MEMS device, and wherein the at least one semiconductor device is also electrically coupled to at least one contact on a first connecting surface of the cap section through internal metal interconnections and at least one pass-through via in the cap section; and
a substrate underlying the cap section comprising at least one contact on a supporting surface.

10. The apparatus of claim 9, further including an enclosure formed in a space between the MEMS device and the cap section, the enclosure being sealed by a seal ring and housing a projected sensor portion of the MEMS device.

11. The apparatus of claim 9, wherein the at least one semiconductor device in the cap section comprises a digital IC, an analog IC, a MEMS control IC, a mixed-signal IC, a microprocessor, a memory IC, an IC in a system-on-a-chip configuration, a micro-strip filter, a micro-strip resonator, and any combination thereof.

12. The apparatus of claim 9, wherein the at least one electronic circuit in the MEMS is coupled to the at least one contact on the supporting surface through internal metal interconnections and the at least one pass-through via in the cap section.

13. The apparatus of claim 9, wherein a pitch of the at least one pass-through via is significantly greater than that of the at least one terminal on the first surface of the MEMS device.

14. The apparatus of claim 9, further comprising a sensor portion projecting over a portion of a second surface of the MEMS device.

15. The apparatus of claim 9, further comprising an interposer between the cap section and the supporting surface, adapting the at least one contact on the first connecting surface of the cap section to the at least one contact on the supporting surface of the substrate.

16. The apparatus of claim 9, wherein the substrate is a packaging substrate, the packaging substrate including a plurality of package leads coupled to the at least one contact on the packaging substrate.

17. The apparatus of claim 9, wherein the substrate is a printed circuit board (PCB) comprising at least one circuit element, the at least one circuit element in the PCB being electrically coupled to the at least one semiconductor device in the cap section through metal traces in the PCB.

18. The apparatus of claim 9, further including at least one bond pad on a second surface of the MEMS device, at least one bond pad on a second connecting surface of the cap section, and at least one bond pad on the supporting surface; wherein the bond pads are electrically coupled through wire bonds.

19. The apparatus of claim 9, wherein the cap section has a multi-cap-layers configuration, and each of the cap layers comprises at least one pass-through via, a digital IC, an analog IC, a MEMS control IC, a mixed-signal IC, a microprocessor, a memory IC, an IC in a system-on-a-chip configuration, a micro-strip filter, a micro-strip resonator, and any combination thereof.

20. The apparatus of claim 19, wherein a pitch of the at least one pass-through via in the multi-cap-layers is different.
